(19) United States
(12) Patent Application Publication
(10) Pub. No.: US 2025/0208785 A1
(43) Pub. Date: Jun. 26, 2025

(54) STORAGE DEVICE AND OPERATING METHOD THEREOF

(71) Applicant: SK hynix Inc., Icheon-si (KR)

(72) Inventor: Jung Ae KIM, Icheon-si (KR)

(21) Appl. No.: 18/945,330

(22) Filed: Nov. 12, 2024

(30) Foreign Application Priority Data
Dec. 21, 2023 (KR) 10-2023-0188012

(51) Int. Cl. G06F 3/06

(52) U.S. Cl. CPC G06F 3/0655; G06F 3/0604; G06F 3/0679

(57) ABSTRACT

A storage device and an operating method of the storage device are provided, which can determine and manage a reliability check target group based on an operating environment of the storage device. In one aspect, an operating method of a storage device comprises dividing, by the controller, weak wordlines having a number of fail bits greater than a predetermined value into a plurality of groups based on the number of fail bits, determining, among the plurality of groups based on operating environment information, target group on which a reliability check is to be performed, performing the reliability check on the target group; and performing a read reclaim operation based on results of the reliability check.

### CROSS-REFERENCE TO RELATED APPLICATION(S)

This patent document claims the benefit 35 U.S.C. 119(a) of Korea Patent Application No. 10-2023-0188012, filed Dec. 21, 2023, the entire contents of which is incorporated herein for all purposes by this reference.

### TECHNICAL FIELD

The present disclosure relates to a storage device and an operating method of the storage device.

### BACKGROUND

A storage device is capable of storing data based on requests of a computer, a mobile terminal such as a smartphone, a tablet PC, etc., and a host such as various electronic devices.

The storage device may further include a controller for controlling a memory (e.g., volatile memory/non-volatile memory). Such a controller receives commands from the host and performs or controls operations to read, write, or erase data in the memory included in the storage device based on the received commands.

### SUMMARY

Some implementations of the disclosed technology provide a storage device capable of grouping weak wordlines into a plurality of groups and managing the weak wordlines by assigning a priority to each of the groups, and an operating method of the same.

Some implementations of the disclosed technology provide a storage device which variably determine and manage a reliability check target group depending on an operating environment of a firmware, and an operating method of the storage device.

In one aspect, a storage device is provided to include a memory for storing data and a controller configured to control the memory. The controller is configured to divide weak wordlines having a number of fail bits greater than a predetermined value into a plurality of groups based on the number of fail bits, determine, among the plurality of groups based on operating environment information, target group on which a reliability check is to be performed, perform the reliability check on the target group, and perform a read reclaim operation based on results of the reliability check.

In another aspect, an operating method of a storage device comprising a memory and a controller is provided. The operating method includes dividing weak wordlines having a number of fail bits greater than a predetermined value into a plurality of groups based on the number of fail bits, determining, among the plurality of groups based on operating environment information, target group on which a reliability check is to be performed, performing the reliability check on the target group and performing a read reclaim operation based on results of the reliability check.

According to the embodiments of the present disclosure, the reliability check target group is variably and flexibly determined and managed depending on an operating environment of a firmware, thereby effectively checking the weak wordline in accordance with the operating environment.

According to the embodiments of the present disclosure, the read reclaim operation can be performed in advance on the uncorrectable error correction code (UECC) that may occur in a test under a temperature condition which must be ensured in a harsh environment (e.g., an environment of a vehicle, etc.), or in an excessive read stress test. Accordingly, it is possible to reduce a probability of the occurrence of a bad block due to the UECC.

### BRIEF DESCRIPTION OF THE DRAWINGS

FIG. 1 shows an example of a schematic configuration of a storage device based on some embodiments of disclosed technology.

FIG. 2 is an example of a block diagram of a controller for performing a reliability check on weak wordlines based on some embodiments of the disclosed technology.

FIG. 3 is an example of a flowchart showing that the reliability check is performed on the weak wordlines based on some embodiments of the disclosed technology.

FIG. 4 is an example of a flowchart showing S310 shown in FIG. 3.

FIG. 5 is an example of a flowchart showing that operating environment information is collected based on some embodiments of the disclosed technology.

FIG. 6 is an example of a flowchart showing a determination whether items included in operating environment information are normal or not based on some implementations of the disclosed technology.

FIG. 7 is an example of a flowchart showing S320 shown in FIG. 3.

FIG. 8 is an example of a view illustrating a method for determining a reliability check target group based on some embodiments of the disclosed technology.

### DETAILED DESCRIPTION

Hereinafter, embodiments of the present disclosure will be described in detail with reference to the accompanying drawings.

In the art, there exists an algorithm for defending NAND disturbance and the algorithm is operated not to affect the performance of the storage device. In the existing algorithm, only some of weak wordlines with a large number of fail bits are selected for a reliability test result and checked, and the certain blocks determined as problematic based on the reliability test result is reclaimed in advance.

However, based on the recent harsh temperature tests and/or read stress tests, in the existing normal environment, the number of fail bits in a wordline other than those determined as the weak wordlines increases. In this case, the fail bits are not filtered by an existing disturbance defense algorithm, which results in a problem to cause an uncorrectable error correction code (UECC). Various implementations of the disclosed technology provide a storage device and an operating method of the storage device, which can determine and manage a reliability check target group based on an operating environment of the storage device.

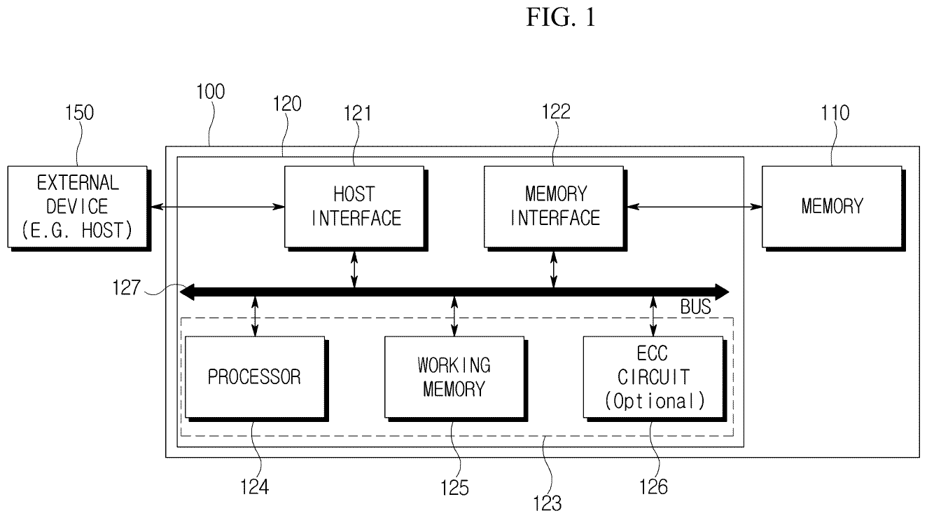

FIG. 1 shows an example of a schematic configuration of a storage device 100 based on embodiments of the present disclosure.

Referring to FIG. 1, the storage device 100 according to the embodiment of the present disclosure may include a memory 110 that stores data, a controller 120 that controls the memory 110.

The memory 110 operates in response to the control of the controller 120. Here, the operation of the memory 110 may include, for example, a read operation, a program operation (also, referred to as a write operation), and an erase operation.

For example, the memory 110 may be implemented in various types such as double data rate synchronous dynamic random access memory (DDR SDRAM), low power double data rate 4 (LPDDR4) SDRAM, graphics double data rate (GDDR) SDRAM, low power DDR (LPDDR), rambus dynamic random access memory (RDRAM), NAND flash memory, 3D NAND flash memory, NOR flash memory, resistive random access memory (RRAM), phase change memory (PRAM), magnetoresistive random access memory (MRAM), ferroelectric random access memory (FRAM), or spin transfer torque random access memory (STT-RAM), etc.

In some implementations, the memory 110 may be implemented to have a three-dimensional array structure. The embodiments of the present disclosure can be applied not only to a flash memory in which a charge storage layer includes a conductive floating gate, but also to a charge trap type flash (CTF) in which the charge storage layer includes an insulation layer.

The memory 110 may receive commands and addresses from the controller 120 and may access an area in a memory cell array selected by an address. Thus, the memory 110 may perform an operation indicated by a command with respect to the area selected by the address.

For example, the memory 110 may perform at least one of a program operation, a read operation, or an erase operation. During the program operation, the memory 110 may program data in the area selected by the address. During the read operation, the memory 110 may read data from the area selected by the address. During the erase operation, the memory 110 may erase data stored in the area selected by the address.

The controller 120 may control the write (program), read, erase, and background operations on the memory 110. For example, the background operation may include, for example, one or more of garbage collection (GC), wear leveling (WL), read reclaim (RR), bad block management (BBM), hyper write migration, or SLC through migration operations, etc. The background operation is not limited thereto and may include other operations.

The controller 120 may control the operation of the memory 110 in accordance with a request from an external device (e.g., a host (HOST)) 150 located outside the storage device 100. In some implementations, the controller 120 may control the operation of the memory 110 independently of the request from the external device 150.

The external device 150 may include a computer, an ultra-mobile PCs (UMPCs), a workstation, a personal digital assistant (PDAs), a tablet PC, a mobile phone, a smart phone, an e-book, a portable multimedia player (PMP), a portable game machine, a navigation system, a black box, a digital camera, a digital multimedia broadcasting (DMB) player, a smart television, a digital audio recorder, a digital audio player, a digital picture recorder, a digital picture player, a digital video recorder, a digital video player, a storage forming a data center, one of various electronic devices constituting a home network, one of various electronic devices constituting a computer network, one of various electronic devices constituting a telematics network, a radio frequency identification (RFID) device, or a mobile device (e.g., a vehicle, a robot, a drone) that travels on the ground, in the water or in the air under human control or autonomously.

The external device 150 may include at least one operating system (OS). The operating system can manage and control overall functions and operations of the external device, and can provide mutual operations between the external device and the storage device 100. The operating system may be divided into a general operating system and a mobile operating system, depending on the mobility of external devices.

In some implementations, the controller 120 and the external device 150 may be provided separately from each other. In some cases, the controller 120 and the external device 150 may be implemented as one integrated device. Hereinafter, for convenience of description, an example will be described in which the controller 120 and the external device 150 are separated from each other.

Referring to FIG. 1, the controller 120 may include a memory interface 122 and a control circuit 123, and a host interface 121.

The host interface 121 provides an interface for communicating with the external device 150. For example, the host interface 121 provides an interface that uses at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, Serial-ATA protocol, a Parallel-ATA protocol, a small computer small interface (SCSI) protocol, an enhanced small disk interface (ESDI) protocol, an integrated drive electronics (IDE) protocol, or a proprietary protocol, etc.

When receiving a command from the external device, the control circuit 123 may receive the command through the host interface 121 and may perform an operation of processing the received command.

The memory interface 122 may be connected to the memory 110 to provide an interface for communicating with the memory 110. Thus, the memory interface 122 may be configured to provide an interface between the memory 110 and the controller 120 based on the control of the control circuit 123.

The control circuit 123 controls the operation of the memory 110 by performing overall control operations of the controller 120. For example, the control circuit 123 may include at least one of a processor 124, a working memory 125, etc., and may selectively include an error detection and correction circuit (ECC) 126, etc.

The processor 124 may control overall operations of the controller 120 and may perform logical operations. The processor 124 may communicate with the external device through the host interface 121 and may communicate with the memory 110 through the memory interface 122.

The processor 124 may perform a function of a flash translation layer (FTL). The processor 124 may convert a logical block address (LBA) provided by the host into a physical block address (PBA) through the flash translation layer (FTL). Through use of a mapping table, the flash translation layer (FTL) may receive the logical block address (LBA) and may convert the logical block address into the physical block address (PBA).

There are various address mapping methods of the flash translation layer depending on a mapping unit. Representative address mapping methods include a page mapping method, a block mapping method, and a hybrid mapping method.

In some implementations, the processor 124 may randomize data received from the external device. For example, the processor 124 may randomize data received from the external device by using a set randomizing seed. The randomized data may be provided to the memory 110 and programmed into the memory cell array of the memory 110.

In some implementations, the processor 124 may de-randomize the data received from the memory 110 during the read operation. For example, the processor 124 may de-randomize the data received from the memory 110 by using a de-randomizing seed. The de-randomized data may be output to the external device.

According to the embodiment, the processor 124 is an application specific integrated circuit (ASIC) where the above-described functions are implemented in the form of logic. The processor 124 can control the operation of the controller 120 based on the functions implemented in hardware.

In some embodiments, the processor 124 is a general-purpose processor or a digital signaling processor (DSP), and may control the operation of the controller 120 by loading and executing firmware. For example, in order to control overall operations of the controller 120 and perform logical operations, the processor 124 may execute (drive) firmware loaded into the working memory 125 during booting.

For example, the firmware may include a flash translation layer (FTL), a host interface layer (HIL), and a flash interface layer (FIL). The flash translation layer (FTL) performs a translation function between a logical address that the external device requests from the storage device 100 and a physical address of the memory 110. The host interface layer (HIL) interprets a command requested from the storage device 100 by the external device 150 and transmits the command to the flash translation layer (FTL). The flash interface layer (FIL) transmits the command instructed by the flash translation layer (FTL) to the memory 110.

Such firmware may be, for example, loaded into the working memory 125 from the memory 110 or a separate non-volatile memory (e.g., ROM, NOR Flash) located outside the memory 110. When executing booting after power-on, the processor 124 may first load all or part of the firmware into the working memory 125.

The processor 124 may perform a logic operation defined in the firmware loaded into the working memory 125 in order to control the overall operation of the controller 120. The processor 124 may store a result of performing the logic operation defined in the firmware in the working memory 125. The processor 124 may control the controller 120 to generate a command or signal in accordance with the result of performing the logic operation defined in the firmware. When the part of the firmware in which the logic operation to be performed is defined is not loaded into the working memory 125, the processor 124 may generate an event (e.g., interrupt) for loading the corresponding part of the firmware into the working memory 125.

In some implementations, the processor 124 may load, from the memory 110, meta data required to drive the firmware. The meta data is for managing the memory 110 and may include management information on user data stored in the memory 110.

In some implementations, the firmware may be updated while the storage device 100 is being produced or while the storage device 100 is running. The controller 120 may download new firmware from the outside of the storage device 100 and may update the existing firmware to the new firmware.

The working memory 125 may store firmware, program codes, commands, or data, which is required to drive the controller 120. The working memory 125 may include, for example, a volatile memory such as one or more of a static RAM (SRAM), a dynamic RAM (DRAM), and/or a synchronous DRAM (SDRAM).

The error detection and correction circuit 126 may detect an error bit of a target data by using an error correction code and may correct the detected error bit. Here, the target data may be or include, for example, data stored in the working memory 125 or data read from the memory 110.

The error detection and correction circuit 126 may be implemented to decode data with the error correction code. The error detection and correction circuit 126 may be implemented with a variety of code decoders. For example, a decoder that performs non-systematic code decoding or a decoder that performs systematic code decoding may be used.

A bus 127 may be configured to provide a channel between the components 121, 122, 124, 125, and 126 of the controller 120. Such a bus 127 may include, for example, a control bus for transmitting various control signals, commands, or others, and a data bus for transmitting various data.

In some implementations, some of the aforementioned components 121, 122, 124, 125, and 126 of the controller 120 may be removed, or some of the aforementioned components 121, 122, 124, 125, and 126 of the controller 120 may be integrated into one. In some cases, in addition to the above-described components of the controller 120, one or more other components may be added.

Under recent harsh temperature tests or read stress tests, the number of fail bits in a wordline other than those determined as the weak wordline having a number of fail bits greater than a predetermined value increases, thus, the fail bits may not be filtered by an existing disturbance defense algorithm, and result in a problem that an uncorrectable error correction code (UECC) is caused.

The following embodiments will describe the storage device which determines and manages a reliability check target group depending on an operating environment, and an operating method of the storage device.

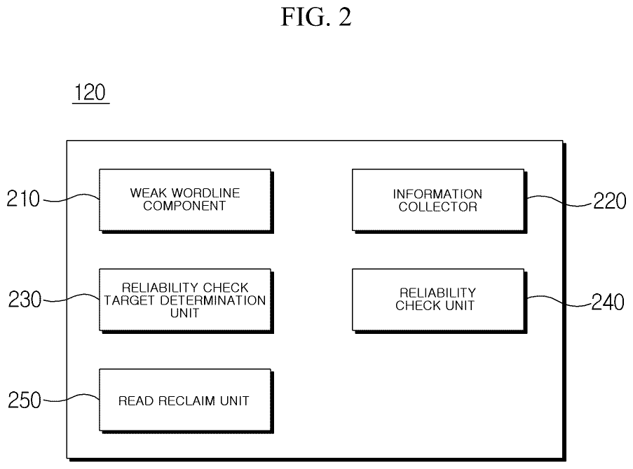

FIG. 2 is a block diagram of a controller for performing a reliability check on weak wordlines based on the embodiments of the present disclosure.

As shown in FIG. 2, the controller 120 includes a weak wordline component 210, an information collector 220, a reliability check target determination unit 230, a reliability check unit 240, and a read reclaim unit 250. The blocks shown are for describing the function of the controller 120, and may not be distinguished by hardware. Thus, the functions performed by the weak wordline component 210, the information collector 220, the check target determination unit 230, the reliability check unit 240, and the read reclaim unit 250 can be performed by the processor 124. One processor 124 may be provided, or a plurality of processors 124 may be provided.

The weak wordline component 210 may divide the weak wordlines selected based on the number of fail bits into a plurality of groups and may assign a priority to each of the groups. For example, the N weak wordlines having a first range of the number of fail bits is grouped as the first group and M weak wordlines having a second range of the number of fail bits is grouped as the second group, the number of fail bits of the weak wordlines in the second group being smaller than the number of fail bits of the weak wordlines in the first group. In this case, the first group of weak wordlines is assigned with a higher priority than the second group of weak wordlines. In this manner, the weak wordline component 210 divides the weak wordlines into multiple groups without being limited two and assign the priority to each group based on the corresponding number of fail bits in the group.

The information collector 220 may collect information for determining the operating environment (hereinafter, referred to as “operating environment information”).

The reliability check target determination unit 230 may determine whether a reliability problem has occurred in the memory 110 based on the collected operating environment information. When a reliability problem occurs, the check target determination unit 230 may determine that the operating environment information indicates an abnormal environment.

The check target determination unit 230 may determine the scope of the reliability check target group that requires reliability check among a plurality of the weak wordline groups, depending on whether the operating environment information represents a normal environment or an abnormal environment.

The reliability check unit 240 may perform a reliability check only on the determined reliability check target group.

The read reclaim unit 250 may perform the read reclaim operation based on the reliability check results of the reliability check unit 240. The read reclaim operation refers to an operation to copy data stored in a memory block into a different memory block before an uncorrectable error occurs at the data stored in the memory. During the read reclaim operation, the read reclaim unit 250 may be controlled by the controller to select certain source memory space and target memory space in the memory to copy data stored in the selected source memory space into the selected target memory space, and then erase the selected source memory space.

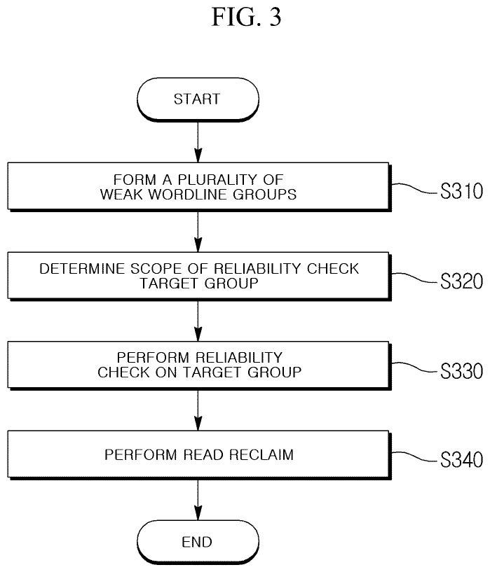

FIG. 3 is a flowchart showing that the reliability check is performed on the weak wordlines based on the embodiments of the present disclosure.

The weak wordline component 210 may divide the weak wordlines into a plurality of groups and may form a plurality of weak wordline groups (S310).

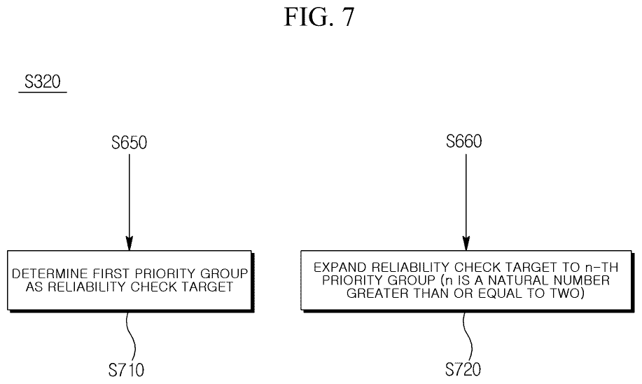

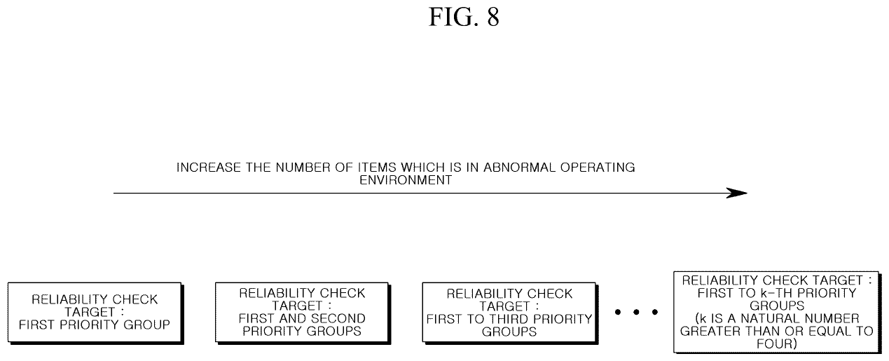

The reliability check target determination unit 230 may determine whether the operating environment information is normal or abnormal, and may determine the scope of the reliability check target group based on the determination result (S320). The determining of the scope of the reliability check target group will be further discussed with reference to FIGS. 7 and 8.

The reliability check unit 240 may perform a reliability check only on the determined reliability check target group among the plurality of weak wordline groups (S330).

After the reliability check is performed, the read reclaim unit 250 may perform the read reclaim operation based on the reliability check result (S340).

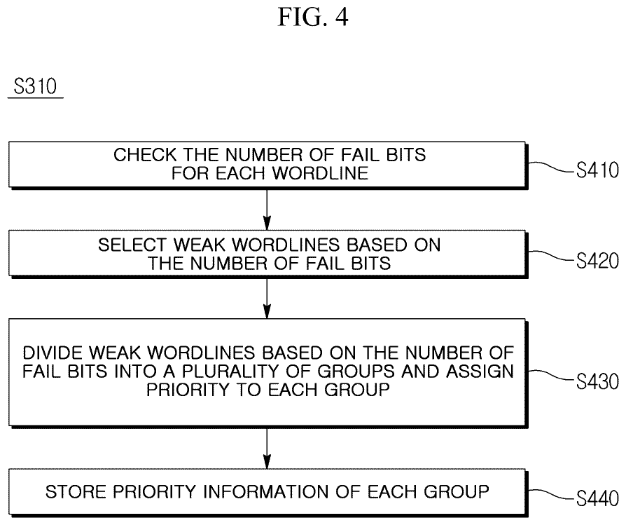

FIG. 4 is an example of a flowchart showing S310 shown in FIG. 3.

The weak wordline component 210 may check the number of fail bits based on reliability test results (S410).

The weak wordline component 210 may select the weak wordlines based on the number of fail bits (S420). For example, the weak wordline component 210 may select the wordlines of which the number of fail bits is larger than a predetermined value.

The weak wordline component 210 may divide the weak wordlines selected based on the number of fail bits into a plurality of groups and may assign a priority to each of the groups (S430). In the example, the weak wordline component 210 may assign a higher priority to a group to which the weak wordline with a relatively large number of fail bits belongs.

The weak wordline component 210 may generate information indicating the selected weak wordlines (e.g., physical addresses of the memory 110 representing the wordlines) such that the information is arranged based on the priority and is generated in the form, for example, of a table.

The weak wordline component 210 may store, in a specific block of the memory 110, the table including the weak wordline information sorted based on the priority (S440).

In this case, the firmware may read the information written in the specific table and may use the information as a reference for operations required by the firmware or may use the information to change memory setting information for specific firmware operations.

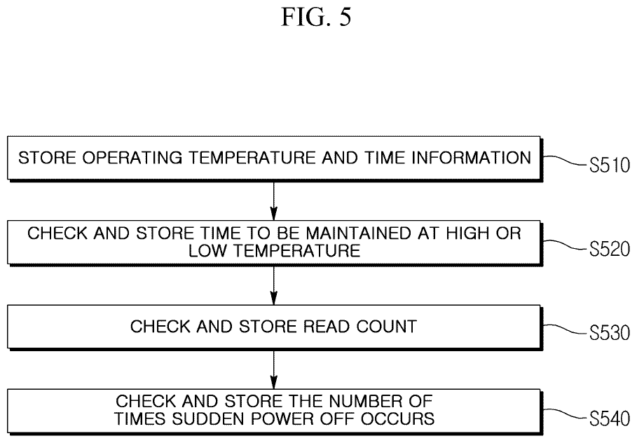

FIG. 5 is an example of a flowchart showing collecting of operating environment information based on the embodiments of the present disclosure.

The information collector 220 may store an operating temperature and time information in a predetermined area of the memory 110 (S510). The operating temperature is a temperature at which the controller 120 is currently being operated and may include the temperature of the controller 120 and the temperature of the memory 110. The time information may refer to a period of time for which the corresponding operating temperature is maintained.

The information collector 220 may check and store a period of time for which the operating temperature is maintained within a specific set temperature range (S520). The specific set temperature range may mean a high or low temperature range that is higher or lower than a regular temperature range. The specific set temperature range and/or the regular temperature range may be predetermined and stored.

For example, the specific set temperature range may include a low temperature range of 0 degrees or less, and a high temperature range of 50 degrees or more. Such values of the temperatures are examples only and values of the low temperature and high temperature, etc., may be defined variously according to characteristics of the memory.

The information collector 220 may check and store a read count of the memory 110 (S530). The read count refers to information on the number of read operations actually performed on the memory 110. In some implementations, the read operation may be performed by the command from the external device. In some implementations, the read operation may be performed independently of the command from the external device. In the implementations, the read count may refer to not only the read count of the read operations performed based on commands of the external device 150 but also the read count of the read operations performed by the controller 120 itself (e.g., Map Read, GC Read, reliability Check Read, etc.) independently of the read commands from the external device 150.

The information collector 220 may check and store the occurrence cycle of sudden power off or the number of times the sudden power off occurs for a predetermined period of time (S540). For example, the information collector 220 may check and store the number of times when the sudden power off occurs for one minute.

In the embodiment of the present disclosure, the reliability check target determination unit 230 may determine whether the operating environment is a normal or abnormal environment by determining whether each item included in the operating environment information is normal or abnormal. The determination of whether the operating environment is normal or not may be started when a specific condition is satisfied. For example, the determination of whether the operating environment is normal or not may be started in order to perform a disturbance check and a retention check.

The disturbance check is an operation that checks, based on the read count, how much read stress has been applied to a programmed cell. Therefore, for the disturbance check, a point of time when to check the weak wordline is required (e.g., when the read count exceeds a predetermined value (e.g., 10 million)) may be a point of time when the operation of S330 starts. The predetermined value compared with the read count to determine whether to check the weak wordline may be predetermined and stored in the storage device.

The retention check is an operation that performs a check in a certain test cycle in order to solve reliability problems due to memory retention characteristics. Therefore, for the retention check, the operation of S330 may start each specific cycle (e.g., 30 seconds or one minute). The specific cycle may be predetermined and stored in the storage device.

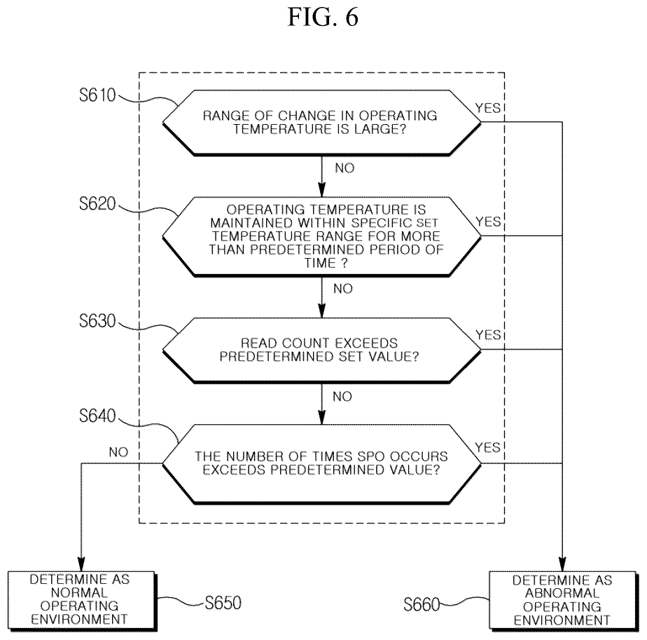

FIG. 6 is a flowchart showing a determination whether the items included in the operating environment information are normal or not based on some implementations. Hereinafter, in the embodiment, predetermined values in S610 to S640 may be set differently for each step.

The reliability check target determination unit 230 may determine whether a range of change in the operating temperature is large (S610). The determination of whether the range of change in the operating temperature is large may be determined based on a set standard.

For example, if a memory allows a temperature from −45 degrees to +105 degrees and room temperature is 25 degrees, when −45 degrees is defined as a low temperature and +105 degrees is defined as a high temperature, it can be determined that sudden temperature change such as room temperature→low temperature, room temperature→high temperature, and low temperature→high temperature shows that the range of change in the operating temperature is large. In some implementations, the sudden temperature change can be determined based on temperature when the number of fail bits rapidly increase. For example, it can be determined whether the range of change in the operating temperature is large based on a temperature condition at a point of time when the number of fail bits rapidly increases. For example, when the operating temperature changes from room temperature to a reference temperature (a temperature at a time point when the number of fail bits suddenly increases), it can be determined that the range of change in the operating temperature is large.

If the result of the determination shows that the range of change in the operating temperature is large, the operating environment may be determined to be an abnormal environment (S660).

If the result of the determination shows that the range of change in the operating temperature is not large, it can be determined whether the operating temperature is maintained within a specific set temperature range for more than a predetermined period of time (S620). The specific set temperature range may mean a high or low temperature range.

If the result of the determination shows that the operating temperature is maintained within a specific set temperature range (high or low temperature range) for more than a predetermined period of time, the reliability check target determination unit 230 may determine the operating environment as an abnormal environment (S660).

If the result of the determination shows that the operating temperature is not maintained within a specific set temperature range (high or low temperature range) for more than a predetermined period of time, the reliability check target determination unit 230 may determine whether the read count exceeds a predetermined value (S630). The predetermined value may be set to 10M, 7M, 5M, or others. Here, M represents 1,000,000. For example, 10M may mean that the read operation has been performed ten million times.

If the result of the determination shows that the read count exceeds the predetermined value, the reliability check target determination unit 230 may determine that a reliability problem has occurred (S660).

If the result of the determination shows that the read count does not exceed the predetermined value, the reliability check target determination unit 230 may determine whether the number of times sudden power off occurs exceeds the predetermined value or not (S640). For example, if the sudden power off (SPO) occurs more than 100 times within one minute, it is determined that the sudden power off has occurred in a short cycle and the reliability check target determination unit 230 may determine the operating environment as an abnormal environment (S660). The reliability check target determination unit 230 may determine whether each item included in the operating environment information represents a normal environment or an abnormal environment.

When none of the determination items in S610 to S640 corresponds to an abnormal environment, the reliability check target determination unit 230 may determine the operating environment as a normal environment (S650).

FIG. 7 is an example of a flowchart showing S320 shown in FIG. 3.

If the result of the determination of whether the operating environment is normal or not by the reliability check target determination unit 230 shows that the operating environment is normal, the reliability check target determination unit 230 may determine only the first priority group among the plurality of weak wordline groups as a reliability check target (S710).

If the result of the determination of whether the operating environment is normal or not by the reliability check target determination unit 230 shows that the operating environment is abnormal, the reliability check target determination unit 230 may include not only the first priority group but also other priority groups (second or lower priority groups) and determine them as a reliability check target (S720). Thus, when the operating environment is determined to be an abnormal environment, the reliability check target determination unit 240 may expand the target groups on which the reliability check is performed to lower priority groups.

In the embodiment of FIG. 6, the reliability check target determination unit 230 determines sequentially each item included in the operating environment information represents a normal environment or an abnormal environment. However, when there is a plurality of items included in the operating environment information, the reliability check target determination unit 230 may determine in parallel whether all of the items represent a normal environment.

FIG. 8 is a view for describing a method for determining the reliability check target group based on the embodiments of the present disclosure.

As shown, when the operating environment is determined to be abnormal, it is determined that the possibility that the operating environment is abnormal increases as the number of items determined to be abnormal increases. Thus, the reliability check target determination unit 230 may expand the reliability check target group according to priorities.

When the scope of the reliability check target group is determined, the reliability check unit 240 may perform the reliability check on the determined target group. Thus, the reliability check unit 250 may perform the reliability check on the determined target group through a test read.

Apart from general read, “Pass” or “Fail” may be determined depending on the level of the fail bit determined by the test read. If “Pass” is determined, normal operation continues, and if “Fail” is determined, operations such as a read reclaim operation may be performed.

In some implementations, the level of the fail bit which is determined by the test read and is used to determine “Pass” or “Fail” may also be operated as a level value determined through a memory reliability test.

As described above, according to the embodiments of the present disclosure, the reliability check target group is variably determined and managed depending on a specific operating environment of the firmware, thereby effectively checking the weak wordline in accordance with the operating environment.

According to the embodiments of the present disclosure, the read reclaim operation can be performed in advance on the uncorrectable error correction code (UECC) that may occur in a test under a temperature condition which must be ensured in a harsh environment (e.g., an environment of a vehicle, etc.), or in an excessive read stress test. Accordingly, it is possible to reduce a probability of the occurrence of a bad block due to the UECC.

While various embodiments have been described above, variations and improvements of the disclosed embodiments and other embodiments may be made based on what is described or illustrated in this document.

I/We claim:

1. A storage device comprising:
a memory for storing data; and
a controller configured to control the memory,
wherein the controller is configured to:
divide weak wordlines having a number of fail bits greater than a predetermined value into a plurality of groups based on the number of fail bits,
determine, among the plurality of groups based on operating environment information, target group on which a reliability check is to be performed,
perform the reliability check on the target group, and
perform a read reclaim operation based on results of the reliability check.

2. The storage device of claim 1, wherein the controller is configured to assign a corresponding priority to each of the plurality of groups such that a higher priority is assigned to a group to which the weak wordline with a relatively large number of fail bits belongs.

3. The storage device of claim 2, wherein the operating environment information comprises operating temperature.

4. The storage device of claim 3, wherein, in response to a range of change in the operating temperature being greater than or equal to a predetermined set value, the controller is configured to determine that the operating environment information indicates an abnormal environment.

5. The storage device of claim 3, wherein, in response to a period of time for which the operating temperature is maintained within a specific set temperature range being greater than or equal to a predetermined period of time, the controller is configured to determine that the operating environment information indicates an abnormal environment.

6. The storage device of claim 3,
wherein the operating environment information further comprises information on a read count of the memory, and
wherein, in response to the read count exceeding a set value, the controller is configured to determine that the operating environment information indicates an abnormal environment.

7. The storage device of claim 6, wherein the read count comprises a read count of read operations performed by receiving read commands from an external device and a read count of read operations performed by the controller without a read command from the external device.

8. The storage device of claim 3, wherein the operating temperature comprises at least one of a temperature of the controller or a temperature of the memory.

9. The storage device of claim 3,
wherein the operating environment information comprises information on the number of times that sudden power off (SPO) occurs for a predetermined period of time, and
wherein, in response to the number of times sudden power off (SPO) being greater than or equal to a predetermined value, the controller is configured to determine that the operating environment information indicates an abnormal environment.

10. The storage device of claim 2, wherein, in response to determining that the operating environment information indicates an abnormal environment, the controller is configured to determine the target group to include a first group with a highest priority and a second group with a second highest priority.

11. An operating method of a storage device comprising a memory and a controller, the operating method comprising:
dividing, by the controller, weak wordlines having a number of fail bits greater than a predetermined value into a plurality of groups based on the number of fail bits;
determining, among the plurality of groups based on operating environment information, target group on which a reliability check is to be performed;
performing the reliability check on the target group; and
performing a read reclaim operation based on results of the reliability check.

12. The operating method of a storage device of claim 11, further comprising assigning a corresponding priority to each of the plurality of groups such that a higher priority is assigned to a group to which the weak wordline with a relatively large number of fail bits belongs.

13. The operating method of a storage device of claim 12, wherein the operating environment information comprises operating temperature.

14. The operating method of a storage device of claim 13, further comprising, in response to a range of change in the operating temperature being greater than or equal to a predetermined set value, determining that the operating environment information indicates an abnormal environment.

15. The operating method of a storage device of claim 13, further comprising, in response to a period of time for which the operating temperature is maintained within a specific set temperature range being greater than or equal to a predetermined period of time, determining that the operating environment information indicates an abnormal environment.

16. The operating method of a storage device of claim 13,
wherein the operating environment information further comprises information on a read count of the memory, and
wherein in response to the read count exceeding a set value, determining that the operating environment information indicates an abnormal environment.

17. The operating method of a storage device of claim 16, wherein the read count comprises a read count of read operations performed by receiving read commands from an external device and a read count of read operations performed by the controller without a read command from the external device.

18. The operating method of a storage device of claim 13, wherein the operating temperature comprises at least one of a temperature of the controller or a temperature of the memory.

19. The operating method of a storage device of claim 13,
wherein the operating environment information comprises information on the number of times that sudden power off (SPO) occurs for a predetermined period of time, and
wherein, in response to the number of times sudden power off (SPO) being greater than or equal to a predetermined value, the operating method further comprises determining that the operating environment information indicates an abnormal environment.

20. The operating method of a storage device of claim 12, further comprising, in response to determining that the operating environment information indicate an abnormal environment, determining the target group to include a first group with a highest priority and a second group with a second highest priority.
